(19) United States
(12) Patent Application Publication
(10) Pub. No.: US 2018/0230591 A1
(43) Pub. Date: Aug. 16, 2018

(54) METHOD FOR MANUFACTURING SILICON NITRIDE THIN FILM USING PLASMA ATOMIC LAYER DEPOSITION METHOD

(71) Applicant: DNF CO., LTD., Daejeon (KR)

(72) Inventors: Se Jin JANG, Daegu (KR); Sang-Do LEE, Daejeon (KR); Sung Woo CHO, Daegu (KR); Sung Gi KIM, Daejeon (KR); Byeong-il YANG, Daejeon (KR); Jang Hyeon SEOK, Sejong (KR); Sang Ick LEE, Daejeon (KR); Myong Woon KIM, Daejeon (KR)

(21) Appl. No.: 15/751,719

(22) PCT Filed: Jul. 14, 2016
(86) PCT No.: PCT/KR2016/007662

§ 371 Date: Feb. 9, 2018

(30) Foreign Application Priority Data
Aug. 12, 2015 (KR) 10-2015-0113759

(51) Int. Cl. C23C 16/02; C23C 16/455; H01L 21/02; C23C 16/513; C23C 16/34; C23C 16/44

(52) U.S. Cl. CPC C23C 16/0245; C23C 16/45525; H01L 21/0228; H01L 21/0217; C23C 16/345; C23C 16/4401; C23C 16/513

(57) ABSTRACT

The present invention relates to a method for manufacturing a silicon nitride thin film using a plasma atomic layer deposition method and, more particularly, the purpose of the present invention is to provide a method for manufacturing a silicon nitride thin film including a high quality Si—N bond under the condition of lower power and film-forming temperature, by applying an aminosilane derivative having a specific Si—N bond to a plasma atomic layer deposition method.

### TECHNICAL FIELD

The present invention relates to a manufacturing method of a silicon nitride thin film using plasma atomic layer deposition, and more particularly, to a manufacturing method of a high-purity silicon nitride thin film by plasma atomic layer deposition using low-power plasma.

### BACKGROUND ART

An insulation film containing Si—N, including a silicon nitride (SiN) thin film and a silicon carbonitride (SiCN) thin film has high resistance to hydrogen fluoride (HF). Therefore, in a manufacturing process of semiconductor devices such as memory and high-density integrated circuit (large scale integrated circuit: LSI), the insulation film containing Si—N may be used in an etching stopper layer when etching a silicon oxide (SiO₂) thin film and the like, for increasing deviation of the resistance value of and a gate electrode, or in a diffusion barrier of a dopant, etc. In particular, a film forming temperature of a silicon nitride film after forming a gate electrode is required to be lowered. For example, when forming a silicon nitride film after forming a gate electrode, the film forming temperature is required to be lower than 760° C. which is the film forming temperature when using conventional low pressure-chemical vapor deposition (LP-CVD), or 550° C. which is the film forming temperature when using atomic layer deposition (ALD).

The ALD is a method of supplying gases which are raw materials of two (or more) kinds used in the film formation one by one alternatively under optional film formation conditions (temperature, time, etc.), thereby being adsorbed by one atomic layer unit, and performing film formation using a surface reaction. For example, a first raw material gas and a second raw material gas are flowed along the surface of an object to be treated, thereby adsorbing the raw material gas molecules of the first raw material gas on the surface of a treating object, and reacting the raw material gas molecules of the second raw material gas with the adsorbed raw material gas molecules of the first raw material gas, thereby forming a film having a thickness of one molecular layer. Further, by repeating this step, a high-quality thin film may be formed on a surface of the object to be treated.

Japanese Patent Laid-Open Publication No. 2004-281853 discloses that in the case of alternatively supplying dichlorosilane (DCS: SiH₂Cl₂) and ammonia (NH₃) by ALD to form a silicon nitride film, the silicon nitride film may be formed at a low temperature of 300 to 600° C. by supplying ammonia radicals (NH₃*) in which ammonia is activated by plasma, however, this silicon nitride film formed at a low temperature using ALD has an increased chlorine (Cl) concentration which has an influence on natural oxidation of the silicon nitride film, or causes resistance to hydrogen fluoride of the silicon nitride film to be reduced, thereby having a high wet etch rate, which leads to a low etch selectivity (selectivity ratio) to the oxidation film. In addition, the silicon nitride film formed at a low temperature has low film stress, so that desired stress strength may not be realized. In order to improve resistance to hydrogen fluoride of the silicon nitride film as described above, a method of introducing carbon (C) into the silicon nitride film may be considered, however, since it may be a factor of structural defects to introduce carbon into the silicon nitride at a low temperature range of 400° C. or less, insulation resistance may be deteriorated.

Korean Patent Publication No. 0944842 discloses a technique of forming a high stress silicon nitride film at a low temperature (390° C. to 410° C.) by ALD, however, a chlorine atom (Cl) which is an undesired atom, contained in a chemical ligand remains in the thin film to cause particles on a substrate surface, thereby making formation of the silicon nitride film having excellent film quality difficult.

The present invention has been contrived for solving low stress strength of a thin film, a high wet etch rate, and reduced film quality, which are the problems of the conventional ALD at a low film forming temperature.

Thus, the present applicant completed the present invention, by depositing an aminosilane derivative or a silazane derivative, using plasma enhanced atomic layer deposition which excites plasma under a predetermined condition, thereby providing a manufacturing method of a silicon nitride thin film including a high-quality Si—N bond, having excellent stress strength, a high deposition rate, and excellent resistance to hydrogen fluoride.

### DISCLOSURE

### Technical Problem

An object of the present invention is to provide a manufacturing method of a high-quality silicon nitride thin film, using plasma atomic layer deposition using low power plasma, for solving the problems of conventional ALD at a low film forming temperature.

### Technical Solution

In one general aspect, a manufacturing method of a silicon nitride thin film by plasma enhanced atomic layer deposition (PEALD) includes: a first step of adsorbing an aminosilane derivative or a silazane derivative on a substrate; and a second step of generating plasma while injecting reaction gas to the substrate, thereby forming an atomic layer of a Si—N bond, wherein power (Pₚ₁) and a dosage (P_{D}) of the plasma satisfy the following conditions:

50 W≤Pₚ₁≤300 W, and

1.0 Wsec/cm²≤P_{D}≤4.0 Wsec/cm².

The plasma according to an exemplary embodiment of the present invention may be irradiated for 1 to 20 seconds.

The manufacturing method of a silicon nitride thin film according to an exemplary embodiment of the present invention may satisfy the power (Pₚ₁) in a range of 75 to 150 W, and the dosage (P_{D}) in a range of 2 to 3.5 Wsec/cm² of the plasma.

In the manufacturing method of a silicon nitride thin film according to an exemplary embodiment of the present invention, pressure when forming the atomic layer may be 0.1 to 100 ton.

In the manufacturing method of a silicon nitride thin film according to an exemplary embodiment of the present invention, a temperature of the substrate may be 200 to 450° C.

In the manufacturing method of a silicon nitride thin film according to an exemplary embodiment of the present invention, the aminosilane derivative may be represented by the following Chemical Formula 1:

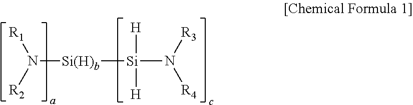

wherein R₁ to R₄ are independently of one another, hydrogen, halogen, (C1-C5) alkyl or (C2-C5) alkenyl; and a, b and c are independently of one another, an integer of 0 to 3, and a+b+c=4.

The aminosilane derivative or silazane derivative according to an exemplary embodiment of the present invention may be selected from the following structures:

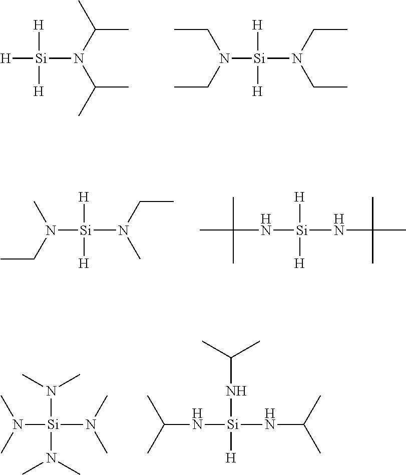

The reaction gas according to an exemplary embodiment of the present invention may be nitrogen (N₂) gas, hydrogen (H₂) gas, ammonia (NH₃) gas, hydrazine (N₂H₄) gas, or mixed gas thereof.

The silicon nitride thin film according to an exemplary embodiment of the present invention may have resistance to hydrogen fluoride (300:1 BOE solution) in a range of 0.01 to 0.20 Å/sec.

The silicon nitride thin film according to an exemplary embodiment of the present invention may have a carbon content of 0.1 atom % or less, or a hydrogen content of 10 atom % or less.

The silicon nitride thin film according to an exemplary embodiment of the present invention may have a silicon/nitrogen compositional ratio in a range of 0.71 to 0.87.

### Advantageous Effects

The manufacturing method according to the present invention may apply an aminosilane derivative having a specific Si—N bond to plasma atomic layer deposition, thereby providing a silicon nitride thin film including a high-quality Si—N bond under the conditions of lower power and film formation temperature.

Further, the manufacturing method according to the present invention may implement a superior deposition rate and excellent stress strength even under the conditions of low power and low film forming temperature, and the thin film manufactured therefrom has a minimized content of impurities such as carbon, oxygen and hydrogen, thereby having high purity and very good physical and electrical properties, and also excellent resistance to hydrogen fluoride.

### DESCRIPTION OF DRAWINGS

FIG. 1 schematically illustrates a deposition method of a silicon nitride thin film according to the present invention.

FIG. 2 illustrates results of analysis using infrared spectroscopy of the silicon nitride thin films manufactured in Example 1 and Comparative Example 1.

FIG. 3 illustrates results of analysis using infrared spectroscopy of the silicon nitride thin films manufactured in Examples 2 to 4, and Comparative Examples 2 and 3.

### BEST MODE

Hereinafter, the manufacturing method of a silicon nitride thin film using plasma enhanced atomic layer deposition will be described, however, technical terms and scientific terms used herein have the general meaning understood by those skilled in the art to which the present invention pertains, unless otherwise defined, and a description for the known function and configuration obscuring the present invention will be omitted in the following description.

The present invention provides a manufacturing method of a silicon nitride thin film using low plasma discharge intensity capable of solving the problems of the conventional ALD at a low film forming temperature, and implementing excellent production efficiency.

The silicon nitride thin film manufactured by a manufacturing method satisfying a predetermined condition according to the present invention may implement excellent stress strength and a deposition rate, and one embodiment thereof is as follows:

The manufacturing method of a silicon nitride thin film according to the present invention may include: a first step of adsorbing an aminosilane derivative or a silazane derivative on a substrate; and a second step of generating plasma while injecting reaction gas to the substrate, thereby forming an atomic layer of a Si—N bond, wherein power (Pₚ₁) and a dosage (P_{D}) of the plasma satisfy the following conditions:

50 W≤Pₚ₁≤300 W, and

1.0 Wsec/cm²≤P_{D}≤4.0 Wsec/cm².

It is preferred that the manufacturing method according to an exemplary embodiment of the present invention is carried out under an inert atmosphere, but not limited thereto, and the inert atmosphere may be created by one or more gases selected from the group consisting of argon (Ar), neon (Ne) and helium (He), but not limited thereto.

In addition, in the second step, the atomic layer of a Si—N bond may be formed, by removing the ligand of the aminosilane derivative or silazane derivative including the Si—N adsorbed by generating plasma while injecting the reaction gas. Herein, the atomic layer of the Si—N bond may be formed by injecting the reaction gas into a chamber and performing excitement using the plasma in the above range to produce reaction gas radicals, and being adsorbed by the reaction gas radicals. Besides, in order to manufacture a high purity silicon nitride thin film, a step of removing an unadsorbed aminosilane derivative after the first step may be further included.

The aminosilane derivative according to the present invention has excellent volatility and high reactivity even at room temperature (23° C.) to 40° C. under atmospheric pressure, and thus, high deposition efficiency is possible by low power plasma enhanced atomic layer deposition at a low substrate temperature of 200 to 450° C., and also high thermal stability and stress strength of the thin film may be implemented.

In addition, the pressure when forming an atomic layer of the plasma enhanced atomic layer deposition may be 0.1 to 100 torr, preferably 0.1 to 10 torr, more preferably 0.1 to 5 torr, but not limited thereto.

In the manufacturing method of a silicon nitride thin film according to an exemplary embodiment of the present invention, the aminosilane derivative may be represented by the following Chemical Formula 1:

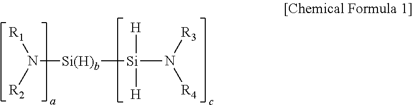

wherein R₁ to R₄ are independently of one another, hydrogen, halogen, (C1-C5) alkyl or (C2-C5) alkenyl; and a, b and c are independently of one another, an integer of 0 to 3, and a+b+c=4.

Herein, when R₁ to R₄ of the aminosilane derivative are independently of one another, hydrogen, methyl, ethyl, n-propyl, i-propyl, n-butyl, i-butyl, s-butyl or t-butyl, they have lower activation energy to produce excellent reactivity and not to produce nonvolatile byproducts, thereby capable of forming a high purity silicon nitride thin film.

Preferably, when performing plasma enhanced atomic layer deposition using the aminosilane derivative or silazane derivative selected from the following structures with plasma power (Pₚ₁) and a dosage (P_{D}) in the following range, a high-quality silicon nitride thin film having excellent stress strength may be formed:

50 W≤Pₚ₁≤300 W, and

1.0 Wsec/cm²≤P_{D}≤4.0 Wsec/cm².

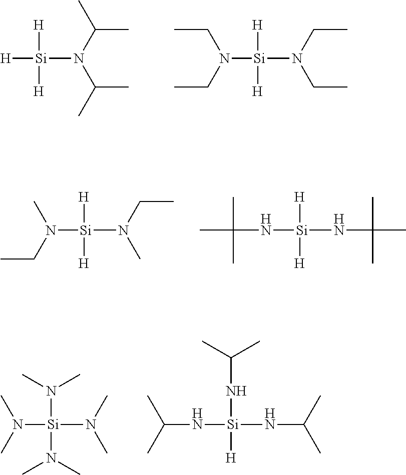

Further, the manufacturing method according to the present invention uses a specific aminosilane derivative as described above, thereby manufacturing a high-quality silicon nitride thin film at a lower substrate temperature than the film forming temperature of the conventional ALD (atomic layer deposition), when satisfying power (Pₚ₁) in a range of 75 to 150 W and a dosage (P_{D}) in a range of 2 to 3.5 Wsec/cm² of the plasma.

Besides, the silicon nitride thin film manufactured by the manufacturing method according to the present invention has excellent resistance to a cleaning solution or an oxide etch solution. As a specific example of the cleaning solution and the oxidation etch solution, hydrogen peroxide (H₂O₂), ammonium hydroxide (NH₄OH), an aqueous phosphoric acid solution (aqueous H₃PO₄ solution), an aqueous hydrogen fluoride solution (aqueous HF solution), a buffered oxide etch solution (BOE) solution, and the like may be listed, but not limited thereto, and the silicon nitride thin film according to the present invention particularly has excellent resistance to hydrogen fluoride.

Thus, the silicon nitride thin film according to an exemplary embodiment of the present invention may have resistance to hydrogen fluoride (300:1 BOE solution) in a range of 0.01 to 0.20 Å/sec, but not limited thereto.

The manufacturing method according to an exemplary embodiment of the present invention may further include a step of injecting inert gas to remove remaining reaction gas and produced byproducts after the second step, thereby providing a silicon nitride thin film including the higher purity atomic layer of a Si—N bond. Herein, the removed remaining reaction gas and produced byproducts may be reaction gas and inert gas which does not react with the aminosilane derivative or silazane derivative, and as a specific example, one or more gases selected from the group consisting of argon (Ar), nitrogen (N₂), helium (He), xenon (Xe), neon (Ne), hydrogen (H₂) and the like may be listed, which may be supplied at a flow rate in a range of 100 to 5000 sccm for 0.1 to 1000 seconds, thereby removing remaining reaction gas and produced byproducts.

The plasma according to an exemplary embodiment of the present invention may be irradiated for 1 to 20 seconds, and in terms of minimizing a carbon atom content and a hydrogen content, it is preferred that the irradiation is carried out for 5 to 15 seconds.

In addition, it is preferred that the power (Pₚ₁) and the dosage (P_{D}) of the plasma according to an exemplary embodiment of the present invention satisfy the power (Pₚ₁) of 75 to 150 W, and the dosage (P_{D}) of 2 to 3.5 Wsec/cm² of the plasma, in terms of forming excellent cohesion and a high deposition rate of the manufactured silicon nitride film, and a high purity atomic layer of a Si—N bond.

The silicon nitride thin film according to an exemplary embodiment of the present invention may be an insulation layer allowing a ratio of impurity atoms other than silicon and nitrogen to be minimized, and also having excellent physical and electrical properties, with a carbon content of 0.1 atom % or less, or a hydrogen content of 10 atom % or less. Herein, the silicon nitride thin film may be an excellent insulation layer to which the atomic layer of the silicon-nitrogen bond is introduced at a high content of a silicon/nitrogen compositional ratio in a range of 0.71 to 0.87. Herein, the atom % refers to a content (atom %) calculated based on 100 of the total atoms of the entire silicon nitride thin film.

In the manufacturing method according to an exemplary embodiment of the present invention, the reaction gas may be one or more reaction gases selected from the group consisting of nitrogen (N₂) gas, hydrogen (H₂) gas, ammonia (NH₃) gas, hydrazine (N₂H₄) gas, and the like. Herein, the reaction gas may be injected at 1 to 1000 sccm as a nitrogen source and transported, but not limited thereto.

In addition, the pressure when forming an atomic layer of the plasma enhanced atomic layer deposition may be 0.1 to 100 torr, preferably 0.1 to 10 torr, more preferably 0.1 to 5 torr, but not limited thereto.

In the manufacturing method according to an exemplary embodiment of the present invention, the substrate temperature for film formation may be 200 to 450° C., preferably 250 to 450° C., more preferably 300 to 450° C., but not limited thereto.

In the manufacturing method according to an exemplary embodiment of the present invention, of course, the manufacturing method according to the present invention may be changed by the compositional change in the aminosilane derivative, the reaction gas and the like when depositing the plasma enhanced atomic layer, supply time change thereof within the above-described range, or the like.

Hereinafter, the present invention will be described in detail by the following Examples. However, the following Examples are only to assist in the understanding of the present invention, and the scope of the present invention is not limited thereto in any sense.

In addition, the following Examples were carried out by the known plasma enhanced atomic layer deposition (PEALD) using commercialized 200 mm single wafer type ALD equipment in a shower head mode. The thickness of the deposited silicon nitride thin film was measured by an ellipsometer (M2000D, Woollam), and a transmission electron microscope, and the composition thereof was analyzed using an infrared spectroscopy (IFS66V/S & Hyperion 3000, Bruker Optiks), an Auger electron spectroscopy (AES, Microlab 350, Thermo Electron), and a secondary ion mass spectrometer (SIMS).

### (Example 1) Manufacture of Silicon Nitride Thin Film by Plasma Atomic Layer Deposition (PEALD) Using Diisopropylaminosilane

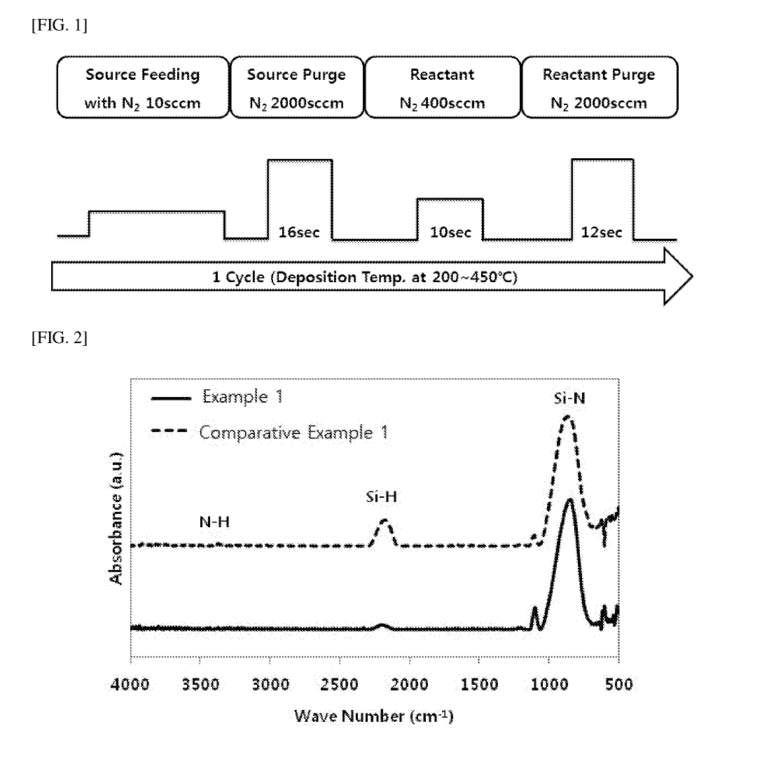

In a common plasma enhanced atomic layer deposition (PEALD) apparatus using the plasma enhanced atomic layer deposition (PEALD), nitrogen (N₂) was injected at a flow rate of 10 sccm onto a silicon wafer substrate (Si wafer) at 300° C., diisopropylaminosilane heated to 35° C. was injected for 0.2 seconds to be adsorbed on the substrate, and then nitrogen (N₂) was injected at a flow rate of 2000 sccm for 16 seconds for purging. On the substrate, plasma of 100 W power was generated, while nitrogen (N₂) was injected thereto at a flow rate of 400 sccm for 10 seconds, thereby forming an atomic layer of a Si—N bond, and then nitrogen (N₂) was injected at a flow rate of 2000 sccm for 12 seconds for purging. The above-described method is set as one cycle, and the cycles were performed 500 times, thereby manufacturing a silicon nitride thin film. A detailed silicon nitride thin film deposition method is shown in the following FIG. 1 and Table 1.

### (Example 2) Manufacture of Silicon Nitride Thin Film by Plasma Atomic Layer Deposition (PEALD) Using Bisdiethylaminosilane

A silicon nitride thin film was manufactured in the same manner as in Example 1, except that instead of diisopropylaminosilane, bisdiethylaminosilane was used, so that the bisdiethylamiosilane heated to 40° C. was injected for 1.0 second.

### (Example 3) Manufacture of Silicon Nitride Thin Film by Plasma Atomic Layer Deposition (PEALD) Using Bisdiethylaminosilane

A silicon nitride thin film was manufactured in the same manner as in Example 2, except that the temperature of the substrate of 300° C. was changed to 400° C.

### (Example 4) Manufacture of Silicon Nitride Thin Film by Plasma Atomic Layer Deposition (PEALD) Using Bisdiethylaminosilane

A silicon nitride thin film was manufactured in the same manner as in Example 2, except that the temperature of the substrate of 300° C. was changed to 450° C.

### (Example 5) Manufacture of Silicon Nitride Thin Film by Plasma Atomic Layer Deposition (PEALD) Using Trisdimethylaminosilane

A silicon nitride thin film was manufactured in the same manner as in Example 1, except that instead of diisopropylaminosilane, trisdimethylaminosilane was used, so that the trisdimethylaminosilane heated to 40° C. was injected for 3.0 seconds.

### (Example 6) Manufacture of Silicon Nitride Thin Film by Plasma Atomic Layer Deposition (PEALD) Using Bis t-Butylaminosilane

A silicon nitride thin film was manufactured in the same manner as in Example 1, except that instead of diisopropylaminosilane, bis t-butylaminosilane was used, so that the bis t-butylaminosilane heated to 20° C. was injected for 1.0 second.

### Comparative Example 1

A silicon nitride thin film was manufactured using the plasma enhanced atomic layer deposition (PEALD) in the same constitution and manner as in Example 1, except that the process is performed under the conditions of a plasma dosage of 10.07 Wsec/cm² at plasma power of 400 W for 10 seconds

### Comparative Example 2

A silicon nitride thin film was manufactured using the plasma enhanced atomic layer deposition (PEALD) in the same constitution and manner as in Comparative Example 1, except that instead of diisopropylaminosilane, bisdiethylaminosilane heated to 40° C. was injected for 1.0 second.

### (Comparative Example 3) Manufacture of Silicon Nitride Thin Film by Plasma Atomic Layer Deposition (PEALD) Using Bisdiethylaminosilane

A silicon nitride thin film was manufactured in the same manner as in Comparative Example 2, except that the plasma power of 400 W was changed to 200 W.

TABLE 1

| | | Example | | | | | | Comparative Example | | |
|---|---|---|---|---|---|---|---|---|---|---|
| | | 1 | 2 | 3 | 4 | 5 | 6 | 1 | 2 | 3 |
| Precursor heating | | 35 | 40 | 40 | 40 | 40 | 20 | 35 | 40 | 40 |
| temperature (° C.) | | | | | | | | | | |
| Substrate | | 300 | 300 | 400 | 450 | 300 | 300 | 300 | 300 | 300 |
| temperature (° C.) | | | | | | | | | | |
| Precursor | Injection | 0.2 | 1 | 1 | 1 | 3 | 3 | 0.2 | 1 | 1 |
| | time (sec) | | | | | | | | | |
| | Chamber | 0.078 | 0.102 | 0.105 | 0.105 | 0.163 | 0.163 | 0.091 | 0.101 | 1.07 |
| | pressure | | | | | | | | | |
| | (Torr) | | | | | | | | | |
| Plasma | Power | 100 | 100 | 100 | 100 | 100 | 100 | 400 | 400 | 200 |
| | (W) | | | | | | | | | |
| | Time | 10 | 10 | 10 | 10 | 10 | 10 | 10 | 10 | 10 |
| | (sec) | | | | | | | | | |
| | Dosage | 2.52 | 2.52 | 2.52 | 2.52 | 2.52 | 2.52 | 10.07 | 10.07 | 5.03 |
| | (Wsec/ | | | | | | | | | |
| | cm²) | | | | | | | | | |
| | Chamber | 0.606 | 0.612 | 0.623 | 0.623 | 0.627 | 0.627 | 0.605 | 0.611 | 0.626 |
| | pressure | | | | | | | | | |
| | (Torr) | | | | | | | | | |

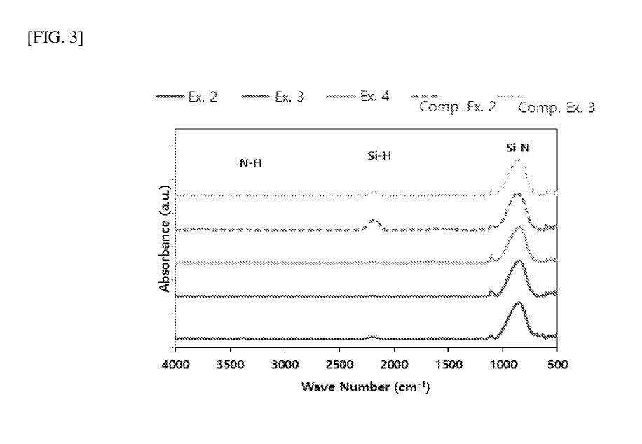

The thicknesses of the silicon nitride thin film manufactured from Examples 1 to 6, and Comparative Examples 1 to 3 were measured by an ellipsometer and a transmission electron microscope (TEM), and the formation of the silicon nitride thin film was observed using an infrared spectroscopy (IR), and the results are illustrated in the following FIGS. 2 and 3.

In addition, the components of the silicon nitride thin film were analyzed using an Auger electron spectroscopy (AES) and a secondary ion mass spectrometer (SIMS), and the results are shown in the following Table 2.

TABLE 2

| | | Wet Etch | | | | | | |
|---|---|---|---|---|---|---|---|---|
| | | Rate | | | | | | |
| | | vs. | | | | | | |
| | Deposition | LPCVD | IR | | Atom compositional ratio | | | H |
| | rate | Si—N | Si—N | Si—N/Si—H | Si/N | Oxygen | Carbon | content |
| | (\acute{Å}/cycle) | 0.014 \acute{Å}/sec | (cm⁻¹) | ratio | Ratio | (atom %) | (atom %) | (%) |
| Example 1 | 0.16 | 3.01 | 849 | 54.48 | 0.75 | 3.57 | 0.00 | 9.29 |
| Example 2 | 0.20 | 3.32 | 858 | 54.88 | 0.71 | 1.65 | 0.00 | 9.79 |
| Example 3 | 0.21 | 12.84 | 846 | 105.34 | 0.80 | 1.70 | 0.00 | 8.37 |
| Example 4 | 0.23 | 2.04 | 846 | 139.97 | 0.81 | 2.32 | 0.00 | 8.19 |
| Example 5 | 0.18 | 4.96 | 860 | 55.62 | 0.87 | 6.31 | 0.00 | 8.99 |
| Example 6 | 0.17 | 5.45 | 852 | 43.78 | 0.76 | 2.03 | 0.00 | 9.58 |
| Comparative | 0.22 | >27.40 | 865 | 9.01 | 0.78 | 7.79 | 0.80 | 13.12 |
| Example 1 | | | | | | | | |
| Comparative | 0.25 | >28.06 | 869 | 5.79 | 0.75 | 2.31 | 0.99 | 15.68 |
| Example 2 | | | | | | | | |
| Comparative | 0.24 | 25.18 | 848 | 14.95 | 0.80 | 2.22 | 0.00 | 13.36 |
| Example 3 | | | | | | | | |

As shown in Table 2, the silicon nitride thin films manufactured in Examples 1 to 5 according to the present invention were confirmed to be high purity silicon nitride thin films having Si—N molecular vibrations observed at 849 to 858 cm⁻¹ in an infrared spectrum, and as a result of Auger electron spectroscopic analysis, having a ratio of Si and N of 0.71 to 0.78. In addition, it was confirmed that high purity silicon nitride thin films were formed from the carbon content of 0.1 atom % or less, the oxygen content of 7 atom % or less, and the hydrogen content of 10 atom % or less in the thin films.

In addition, as shown in Table 2, it was confirmed that the silicon nitride thin films manufactured in Examples 1 to 5 had resistance to hydrogen fluoride (300:1 BOE solution) of 2.04 to 4.96 times, as compared with the resistance of the silicon nitride thin film (0.014/sec) formed using dichlorosilane (SiH₂Cl₂) and ammonia (NH₃) at 770° C. by low pressure chemical vapor deposition (LPCVD), and the resistance value is 0.1 times or less of the Comparative Examples. Thus, it was recognized that the resistance to hydrogen fluoride of Examples 1 to 5 according to the present invention was better than Comparative Examples 1 to 3.

In particular, when the nitrogen (N₂) plasma power is 75 to 100 W, a silicon nitride thin film having better quality may be formed by minimizing the carbon content and the hydrogen content in the thin film.

From the above results, the present invention is expected to be highly valued for using in formation of a high-quality silicon nitride thin film having a high deposition rate and excellent etch resistance by a plasma enhanced atomic layer deposition process using lower power.

1. A manufacturing method of a silicon nitride thin film by plasma enhanced atomic layer deposition (PEALD), the manufacturing method comprising:
adsorbing an aminosilane derivative or a silazane derivative on a substrate; and
generating plasma while injecting reaction gas to the substrate, thereby forming an atomic layer of a Si—N bond,
wherein power (Pₚ₁) and a dosage (P_{D}) of the plasma satisfy the following conditions:
50 W≤Pₚ₁≤300 W, and
1.0 Wsec/cm²≤P_{D}≤4.0 Wsec/cm².

2. The manufacturing method of claim 1, wherein the plasma is irradiated for 1 to 20 seconds.

3. The manufacturing method of claim 2, wherein the power (Pₚ₁) in a range of 75 to 150 W, and the dosage in a range of 2 to 3.5 Wsec/cm² of the plasma are satisfied.

4. The manufacturing method of claim 2, wherein pressure when forming the atomic layer is 0.1 to 100 torr.

5. The manufacturing method of claim 1, wherein temperature of the substrate is 200 to 450° C.

6. The manufacturing method of claim 1, wherein the aminosilane derivative is represented by the following Chemical Formula 1: 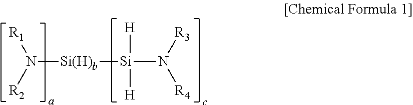
wherein
R₁ to R₄ are independently of one another, hydrogen, halogen, (C1-C5) alkyl or (C2-C5) alkenyl; and
a, b and c are independently of one another, an integer of 0 to 3, and a+b+c=4.

7. The manufacturing method of claim 6, wherein the aminosilane derivative or silazane derivative is selected from the following structures:

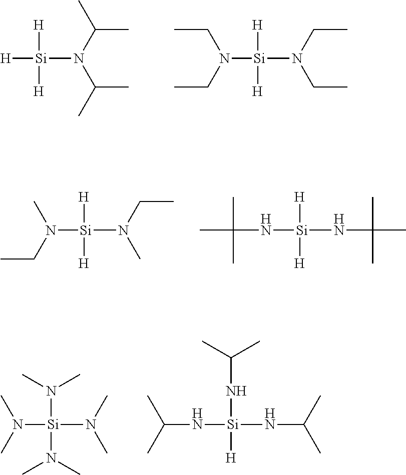

8. The manufacturing method of claim 1, wherein the reaction gas is nitrogen (N₂) gas, hydrogen (H₂) gas, ammonia (NH₃) gas, hydrazine (N₂H₄) gas, or mixed gas thereof.

9. The manufacturing method of claim 1, wherein the silicon nitride thin film has resistance to hydrogen fluoride (300:1 BOE solution) in a range of 0.01 to 0.20 Å/sec.

10. The manufacturing method of claim 1, wherein the silicon nitride thin film has a carbon content of 0.1 atom % or less, or a hydrogen content of 10 atom % or less.

11. The manufacturing method of claim 10, wherein the silicon nitride thin film has a silicon/nitrogen compositional ratio in a range of 0.71 to 0.87.
